(19) United States
(12) Patent Application Publication
(10) Pub. No.: US 2013/0341581 A1
(43) Pub. Date: Dec. 26, 2013

(54) DEVICE, A METHOD FOR MEASURING TEMPERATURE AND A PROGRAMMABLE INSULATOR-SEMICONDUCTOR BIPOLAR TRANSISTOR

(71) Applicants: Dan Ritter, Haifa (IL); Eilam Yalon, Kibbutz Ein Carmel (IL)

(72) Inventors: Dan Ritter, Haifa (IL); Eilam Yalon, Kibbutz Ein Carmel (IL)

(21) Appl. No.: 13/913,448

(22) Filed: Jun. 9, 2013

Related U.S. Application Data
(60) Provisional application No. 61/658,930, filed on Jun. 13, 2012.

(51) Int. Cl. H01L 45/00; G01K 7/01

(52) U.S. Cl. CPC H01L 45/12; G01K 7/01
USPC 257/2; 702/130

(57) ABSTRACT

A memory device, a programmable insulator-semiconductor bipolar transistor (PISBT) and a method for measuring a temperature of a filament, the method may include: providing base voltages of different values to a base of the PISBT; obtaining measurement results by measuring a minority carrier current that flows from a collector of the PISBT in response to the providing of the base voltages of the different values; and calculating the temperature of the filament, based upon the measurement results; wherein the filament is formed in a variable resistance layer of the PISBT when the PISBT is programmed to a certain value out of multiple programmable values, wherein the filament facilitates a flow of minority carriers from an emitter of the PISBT.

### RELATED APPLICATIONS

This patent application claims priority from U.S. provisional patent application Ser. No. 61/658,930 filing date Jun. 13, 2012 which is incorporated herein by reference.

### BACKGROUND

Traditional memory devices are expected to reach their scaling limitations during the next couple of years. There is a growing need to provide more compact memory devices.

### SUMMARY OF THE INVENTION

According to an embodiment of the invention a method for measuring a temperature of a filament may be provided and may include providing base voltages of different values to a base of a programmable insulator-semiconductor bipolar transistor; obtaining measurement results by measuring a minority carrier current that flows from a collector of the programmable insulator-semiconductor bipolar transistor in response to the providing of the base voltages of the different values; and calculating the temperature of the filament, based upon the measurement results; wherein the filament is formed in a variable resistance layer of the programmable insulator-semiconductor bipolar transistor when the programmable insulator-semiconductor bipolar transistor is programmed to a certain value out of multiple programmable values, wherein the filament facilitates a flow of minority carriers from an emitter of the programmable insulator-semiconductor bipolar transistor towards the collector.

The calculating of the temperature may be responsive to a derivative of the minority carrier current with respect to the base voltage.

The calculating of the temperature may be responsive to a charge (q) of a minority carrier, Boltzman's constant (K), and a value of an energy barrier Φ_{B}, that is formed for a certain voltage drop across a tunneling gap formed between the filament and a semiconductor layer of the programmable insulator-semiconductor bipolar transistor.

The calculating of the temperature may include solving the following equation:

$$\frac{d ln ( {I}_{C} )}{d {V}_{B}} = \frac{d T}{d {V}_{B}} [ \frac{{Φ}_{B} - {qV}_{B}}{{kT}^{2}} - \frac{2}{T} ] + \frac{q}{kT} ,$$

wherein d ln(Ic)/dVb is a derivative of a logarithm of a collector current with respect with a base voltage; wherein ΦB represents an energy barrier formed between valance and conduction bands of a p-n junction formed in the programmable insulator-semiconductor bipolar transistor, wherein dT/dVb is a derivative of a temperature with respect to the base voltage.

The calculating of the temperature may be responsive to a filament tip area (S), to a tunneling transmission probability (P) through the filament and into a semiconductor layer of the insulator-semiconductor bipolar transistor; to a minority carrier mass (m*), to a charge (q) of a minority carrier, to an energy barrier (ΦB), and to Boltzman's constant (k).

The method may include solving the following equation:

$${I}_{C} = S \cdot P \cdot \frac{4 π m * k}{{h}^{3}} \cdot T {\int }_{{φ}_{B}}^{∞} ln [ 1 + exp ( - \frac{( E - qV )}{kT} ) ] d E .$$

The calculating of the temperature may be responsive to filament tip area (S), to a tunneling transmission probability (P) through the filament and into a semiconductor layer of the insulator-semiconductor bipolar transistor; to An effective Richardson constant (A*), to a charge (q) of a minority carrier, to an energy barrier (ΦB), and to Boltzman's constant (k).

The calculating of the temperature may include solving the following equation:

$${I}_{C} = S \cdot P \cdot A * {T}^{2} exp [ \frac{- ( {Φ}_{B} - qV )}{kT} ] .$$

The method may include responding to the calculating of the temperature.

The responding may include reducing a temperature of the programmable insulator-semiconductor bipolar transistor.

According to an embodiment of the invention a memory device may be provided and may include (a) selection circuitry; (b) an array of programmable insulator-semiconductor bipolar transistors, each programmable insulator-semiconductor bipolar transistor may include a substrate, a first semiconductor layer; a second semiconductor layer; a variable resistance layer; an emitter electrode; a collector electrode; and a base electrode; wherein the collector electrode is coupled to the substrate; wherein the variable resistance layer is coupled between the emitter electrode and the first semiconductor layer; wherein the second semiconductor layer is coupled between the substrate and the first semiconductor layer; wherein the first and second semiconductor layer define a p-n junction; wherein the variable resistance layer facilitates a flow of minority carriers from the emitter electrode towards the first and second semiconductor layers when being programmed to be of a high resistance value and wherein the variable resistance layer substantially may be arranged to act as an insulator when being programmed to be of a low resistance value; wherein the high resistive value exceeds the low resistive layer; (c) a read circuit; and (d) a write circuit; wherein the selection circuitry may include a controller, multiple column selection lines, and multiple row selection lines; wherein each column selection line is coupled to base electrodes of programmable insulator-semiconductor bipolar transistors that belong to a column of the array; wherein each row selection line is coupled to emitter electrodes of programmable insulator-semiconductor bipolar transistors that belong to a row of the array; wherein the read circuit is coupled to collector electrodes of multiple programmable insulator-semiconductor bipolar transistors of the array; and wherein the write circuit may be arranged to provide a programming voltage between a base electrode and an emitter electrode of a programmable insulator-semiconductor bipolar transistor selected by the selection circuitry; wherein a value of the programming voltage determines a value of the variable resistance layer of the selected programmable insulator-semiconductor bipolar transistor.

The write circuit may be arranged to set the value of the variable resistance layer to a high resistance value that substantially prevents minority carriers to flow through the variable resistance layer.

The write circuit may be arranged to set the value of the variable resistance layer to a high resistance value that allows minority carriers to flow through the variable resistance layer.

The write circuit may be arranged to set the value of the variable resistance layer to a value out of more than two distinguishable values.

The memory device according to claim 14 wherein the read circuit may be arranged to distinguish between the at least two distinguishable values.

There may be provided a programmable insulator-semiconductor bipolar transistor, may include: a substrate, a first semiconductor layer; a second semiconductor layer; a variable resistance layer; an emitter electrode; a collector electrode; and a base electrode; wherein the collector electrode is coupled to the substrate; wherein the variable resistance layer is coupled between the emitter electrode and the first semiconductor layer; wherein the second semiconductor layer is coupled between the substrate and the first semiconductor layer; wherein the first and second semiconductor layer define a p-n junction; wherein the variable resistance layer facilitates a flow of minority carriers from the emitter electrode towards the first and second semiconductor layers when being programmed to be of a high resistance value and wherein the variable resistance layer substantially may be arranged to act as an insulator when being programmed to be of a low resistance value; wherein the high resistive value exceeds the low resistive layer.

The variable resistance layer may be made of Hf02.

The first semiconductor layer may be a p-type doped semiconductor layer and the second semiconductor layer is a n-type doped semiconductor layer.

The emitter electrode may span along an entire upper surface of the variable resistance layer.

There may be provided a method for programming, the method may include: selecting a selected programmable insulator-semiconductor bipolar transistor to be programmed out of an array of programmable insulator-semiconductor bipolar transistors; and providing to the selected programmable insulator-semiconductor bipolar transistor, via selection lines, a base emitter voltage of a value that sets a resistance of a programmable resistance layer of the selected programmable insulator-semiconductor bipolar transistor.

There may be provided a method for reading a programmable insulator-semiconductor bipolar transistor, the method may include: selecting a selected programmable insulator-semiconductor bipolar transistor to be read out of an array of programmable insulator-semiconductor bipolar transistors; providing a voltage to an emitter of the selected programmable insulator-semiconductor bipolar transistor, via a selection line; detecting an absence of a minority carrier current or a parameter of the minority carrier current that flows through the selected programmable insulator-semiconductor bipolar transistor; and determining a value stored in the selected programmable insulator-semiconductor bipolar transistor based upon an outcome of the detecting.

Additional embodiments of the invention include a device arranged to execute any or all of the methods described above, including any stages—and any combinations of same. For example, the device may include

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a cross sectional view of a programmable insulator-semiconductor bipolar transistor according to an embodiment of the invention;

FIG. 2 is a cross sectional view of a programmable insulator-semiconductor bipolar transistor according to an embodiment of the invention;

FIG. 3 illustrates a model of a programmable insulator-semiconductor bipolar transistor and its environment according to an embodiment of the invention;

FIG. 4 illustrates a memory device according to an embodiment of the invention;

FIG. 5 illustrates a method according to an embodiment of the invention;

FIG. 6 illustrates a method according to an embodiment of the invention;

FIG. 7 includes an energy band diagram of a MIS-BT and a cross sectional view of the MIS-BT showing a conductive filament and a tunneling gap formed in the variable resistive layer of the MIS-BT according to an embodiment of the invention;

FIG. 8 illustrates base and collector currents versus base emitter voltage according to an embodiment of the invention;

FIG. 9 illustrates base and collector currents versus base emitter voltage at a low resistance state (LRS) according to an embodiment of the invention;

FIGS. 10A-10C are energy band diagrams according to an embodiment of the invention;

FIGS. 11A-11B illustrate base and collector currents versus base emitter voltage according to various embodiments of the invention;

FIG. 12 illustrates a collector current versus base emitter voltage according to an embodiment of the invention;

FIGS. 13A-13B illustrate a temperature of a filament versus squares of the base and collector currents according to an embodiment of the invention;

FIG. 14 illustrates base and collector currents versus base emitter voltage according to an embodiment of the invention; and

FIG. 15 illustrates a method according to an embodiment of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

### A Programmable Insulator-Semiconductor Bipolar Transistor

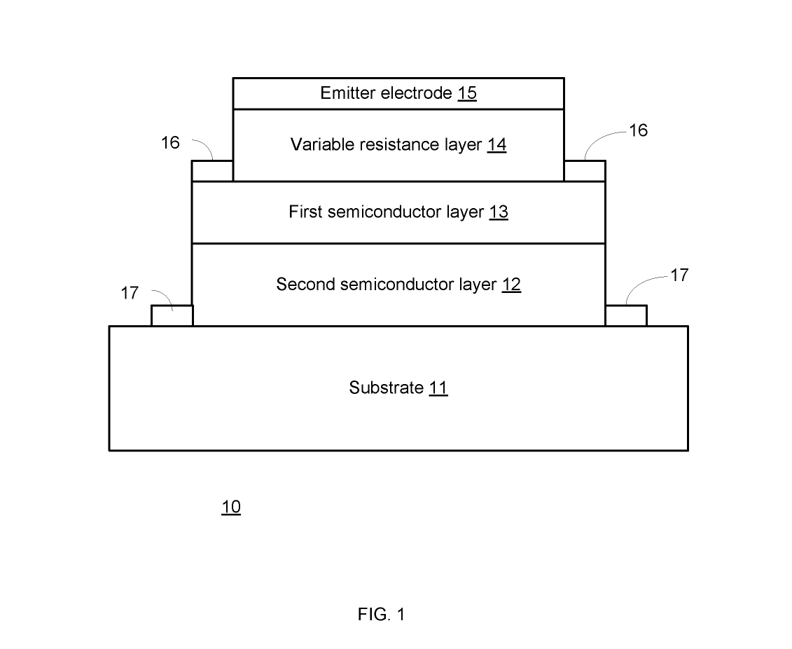

FIG. 1 illustrates a programmable insulator-semiconductor bipolar transistor 10 according to an embodiment of the invention.

The programmable insulator-semiconductor bipolar transistor 10 may include a substrate 11, a first semiconductor layer 13, a second semiconductor layer 12, a variable resistance layer 14, an emitter electrode 15, a collector electrode 17, and a base electrode 14.

The collector electrode 17 is coupled to the substrate 11. The variable resistance layer 14 is coupled between the emitter electrode 15 and the first semiconductor layer 13. The second semiconductor layer 12 is coupled between the substrate 11 and the first semiconductor layer 13. The first and second semiconductor layers 12 and 13 define a p-n junction.

The variable resistance layer 14 may facilitate a flow of electrons, which in the semiconductor layers becomes either minority carriers or majority carriers (electrons or holes), from the emitter electrode towards the first and second semiconductor layers when being programmed to be have low resistance value (when at a low resistance state—LRS). The variable resistance layer may also be programmed to be in a high resistance state (HRS) during which it substantially acts as an insulator wherein the high resistance value exceeds the low resistive layer. The terms high and low are used to indicate that the high resistance value exceeds the low resistance value.

The first semiconductor layer 13 may be p-type doped or n-type doped and the second semiconductor layer 12 may be n-type doped or p-type doped respectively.

The emitter electrode 15 may span along an entire upper surface of the variable resistance layer 14 but this is not necessarily so.

The following text may refer, for simplicity of explanation, to a programmable insulator-semiconductor bipolar transistor such as a metal insulator semiconductor bipolar transistor (MIS-BT) having a variable resistance layer made of HfO2. It is noted that variable resistance layers can be made from other materials, including metallic compounds or non-metallic materials. Non-limiting examples of materials may include hafnium oxide, titanium oxide and silicon oxide.

Among many types of resistance-switching oxides, HfO₂ is an attractive material since it exhibits reproducible switching characteristics and is already used as a high-K dielectric in silicon technology. There is provided an analysis of a metal insulator semiconductor bipolar transistor (MIS-BT) having an HfO2 layer. The HfO₂ based resistive switching (RS) devices exhibit superior switching behavior.

The MIS-BT may include of a metal emitter that injects electrons through a variable resistance layer into the semiconductor conduction and valence bands of the semiconductor layers of the MIS-BT.

The variable resistance layer may also be referred to as an insulating layer—as it is expected to be programmed to a high resistance state (HRS) during which it acts like an insulator and may prevent the passage of minority carriers through the variable resistance layer. The variable resistance layer may be made of a material that differs from a semiconductor material. Accordingly—the terms “variable resistance layer” and “insulator layer” are used in an interchangeable manner in the specification.

A p-n junction such as a shorted or a backward biased p-n junction (formed by n-type doped and p-type doped semiconductor layers) may collect the injected minority carriers as in a conventional bipolar transistor. The structure may be identical to the tunneling emitter bipolar transistor, except that electron injection is not due to direct tunneling from the metal electrode and that there is a variable resistance layer of variable resistance that can be programmed.

If the injection rate of minority carriers from the metal emitter into the base is larger than the injection rate of majority carriers into the metal then current gain can be achieved. The MIS-BT detects injection into the valence and conduction bands separately and thus provides additional information on charge conduction through insulators that cannot be obtained from metal insulator metal (MIM) devices.

An array of MIS-BTs can eliminate the so-called “sneak path” current that may flow when reading a “cross-bar” array of passive memory cells (such as resistive memory cells, phase change memory cells and any passive memory cell array), wherein the “sneak path” may flow through memory cells adjacent to the memory cell that is being read. According to an embodiment of the invention the MIS-BT may include a p-n junction that is operated at zero bias. The requirements from the p-n junction may be relaxed compared to p-n diodes used as serial selection devices or to p-n junction in vertical bipolar transistors as in a binary MIS-BT the presence or absence of minority carrier current is detected.

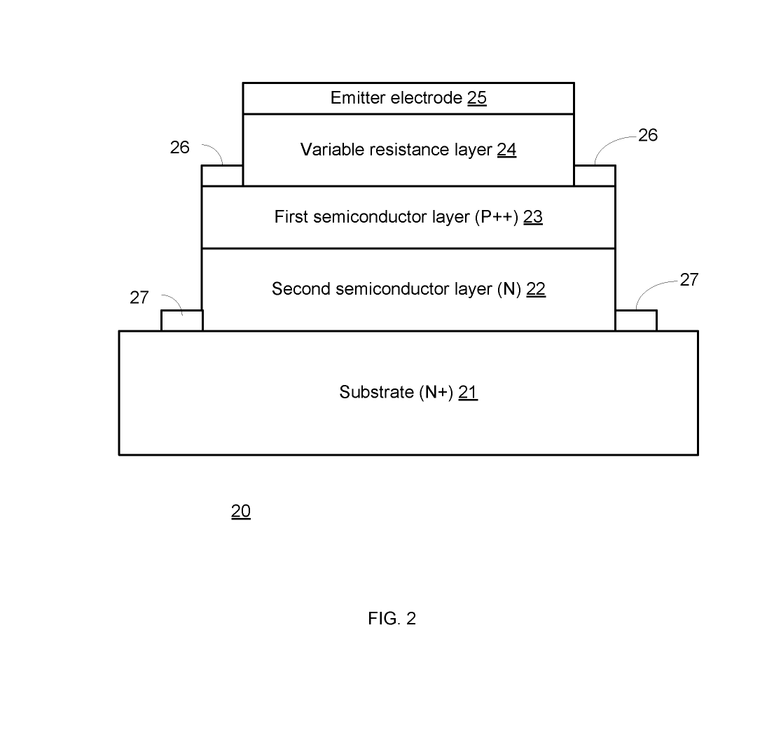

FIG. 2 shows a cross section and a schematic band diagram of the MIS-BT 20 according to an embodiment of the invention.

MIS-ST 20 includes (from bottom to top) a substrate (n-type doped such as slightly n-type doped) 21, a second semiconductor layer (n-type doped—N) 22, a first semiconductor layer (p-type doped or even highly p-type doped—P++) 23, and a variable resistance layer 24. MIS-BT also includes an emitter electrode 25 (formed on top of the variable resistance layer 24), a base electrode (formed on top of the first semiconductor layer 23) 26 and a collector electrode 27 (formed on top of the substrate 21).

It is noted that any of the layers can be doped in another manner (level and/or doping type).

According to an embodiment of the invention the MIS-TS 20 is made of an epitaxial semiconductor stack that was grown by a compact metal organic molecular beam epitaxy system. The insulating HfO₂ layers were deposited by atomic layer deposition. The layer structure of the device is shown in Table I.

TABLE I

| Thickness | | | |
|---|---|---|---|
| (nm) | Material | Doping (cm−3) | Description |
| 15/15/200 | Ti/Pt/Au | — | Metal Contacts (electrodes |
| | | | 25, 26 and 27) |
| 10 | HfO₂ | — | Insulator (ALD) 24 |
| 20 | InGaAs | p = 3 · 10¹⁹ | Base (MOMBE) - first |
| | | | semiconductor layer 23 |
| 200 | InGaAs | undoped | Collector (MOMBE), |
| | | | second semiconductor layer |
| | | | 22 |
| Substrate | InP | n = 1 · 10¹⁹ | Collector contact |
| | | | (N substrate) 21 |

The HfO₂ layers were wet etched using HF:H₂O (1:5) solution. The metal stack was prepared by the lift-off technique. The emitter area was 70×80 μm². As evident in the band diagram, electrons injected from the metal emitter into the base valence and conduction bands constitute the base and collector current, respectively. Minority carriers that recombine in the base or at the interface and electrons injected into interface band-gap states are also detected as base current.

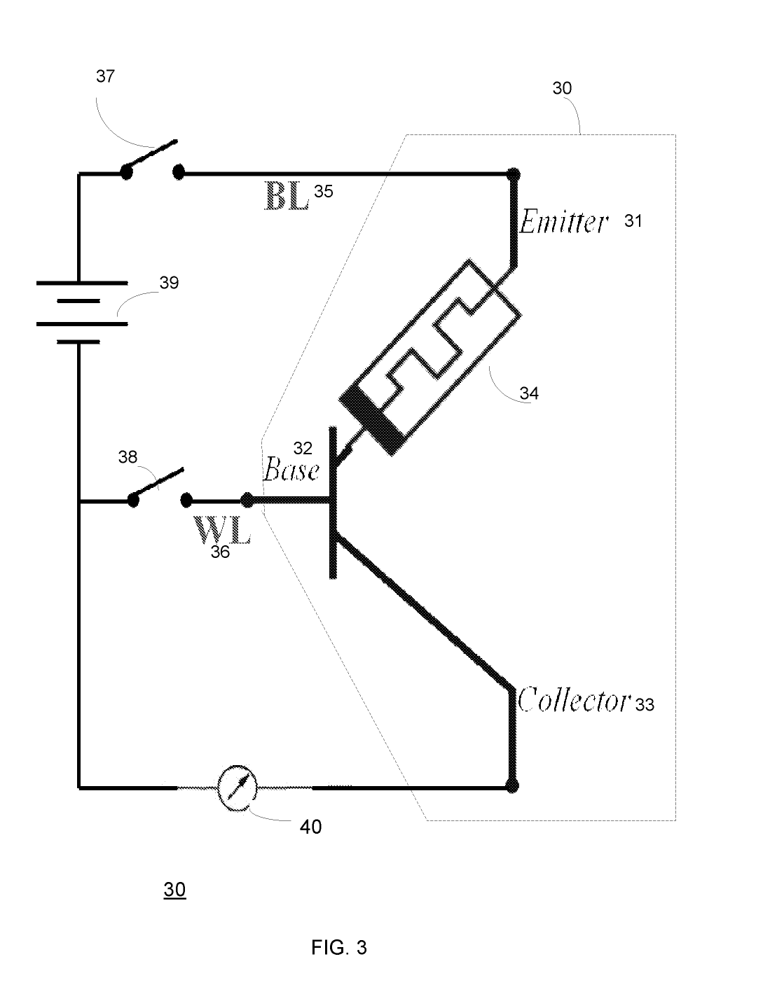

FIG. 3 shows a model 30 of a programmable insulator-semiconductor bipolar transistor such as MIS-BT 20 and its environment according to an embodiment of the invention.

The MIS-BT 20 is illustrated as a bipolar transistor having a base 32, a collector 33 and an emitter 31. The variable resistance layer is illustrated as a variable resistor 34.

The base 32 is connected to a word line 36 while the emitter 31 is connected to a bit line 35. A bit line 35 may be shared by multiple MIS-BTs of a same column while a word line 36 may be shared by multiple MIS-BTs of a same row or vice verse. A MIS-BT of an array of MIS-BTs that are arranged in columns and rows can be selected by providing appropriate base emitter voltage over the bit line 35 and the word line 36 connected to the selected MIS-BT.

The selection circuit that selects the selected MIS-BT is shown as a voltage source 29 and two switches 37 (connected to bit line 35) and 38 (connected to word line 36).

A read circuit 40 is connected to the collectors of all MIS-BTs (or just to a to a sub-a array of MIS-BTs) of the array and can perform a read operation—if a selected MIS-BT is in a high resistance state (HRS) it is not expected to detect any current, wherein if the selected MIS-BT is in a low resistance state (LRS) the read circuit 40 is expected to detect minority carriers injected by the selected MIS-BT.

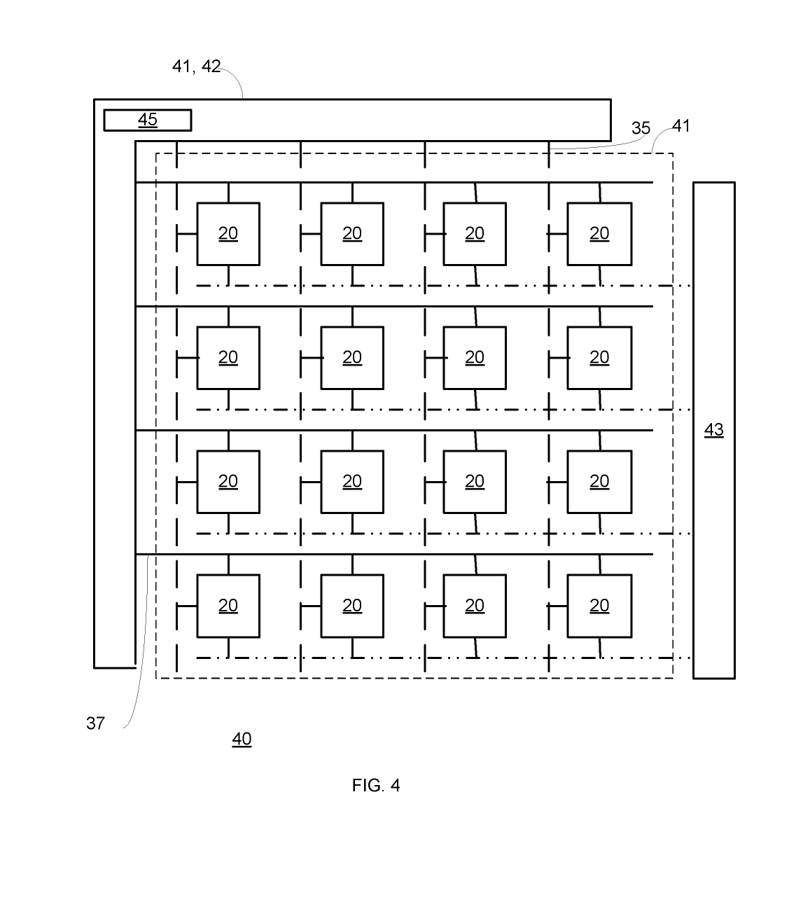

FIG. 4 illustrates a memory device 40 according to an embodiment of the invention.

The memory device 40 may include a selection circuitry 42, an array 41 of programmable insulator-semiconductor bipolar transistors 20, a read circuit 43 and a write circuit 44.

The selection circuitry 42 may include a controller 45, multiple column selection lines such as bit lines 35, and multiple row selection lines such as word lines 37.

Each column selection line is coupled to base electrodes of programmable insulator-semiconductor bipolar transistors 20 that belong to a column of the array 41.

Each row selection line is coupled to emitter electrodes of programmable insulator-semiconductor bipolar transistors 20 that belong to a row of the array 41.

The read circuit 43 is coupled to collector electrodes of programmable insulator-semiconductor bipolar transistors 29 of the array 41. It is noted that the collector electrodes can be grouped to multiple groups and the multiple groups of collector electrodes can be connected to the read circuit or to multiple read circuits such as read circuit 43.

The write circuit 44 is arranged to provide a programming voltage between a base electrode and an emitter electrode of a selected programmable insulator-semiconductor bipolar transistor (selected by the selection circuitry 42). A value and/or polarity of the programming voltage determine a value of the variable resistance layer of the selected programmable insulator-semiconductor bipolar transistor 20.

The write circuit 44 may be arranged to set the value of the variable resistance layer to a high resistance value that substantially prevents minority carrier injection through the variable resistance layer.

The write circuit 44 may be arranged to set the value of the variable resistance layer to a high resistance value that allows minority carrier injection through the variable resistance layer.

The write circuit 44 may be arranged to set the value of the variable resistance layer to a value out of more than two distinguishable values. And the read circuit 43 may be arranged to distinguish between the at least two distinguishable values.

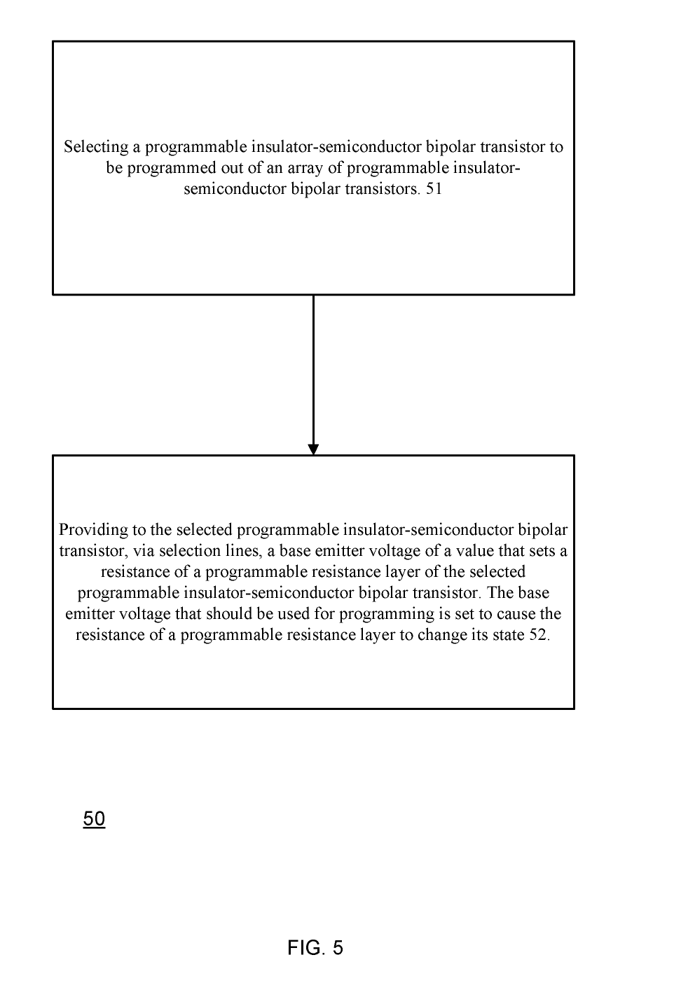

FIG. 5 illustrates method 50 for programming a programmable insulator-semiconductor bipolar transistor of an array according to an embodiment of the invention.

Method 50 may start by stage 51 of selecting a programmable insulator-semiconductor bipolar transistor to be programmed out of an array of programmable insulator-semiconductor bipolar transistors. In case that there is only a single transistor in the array method 50 may start by stage 52.

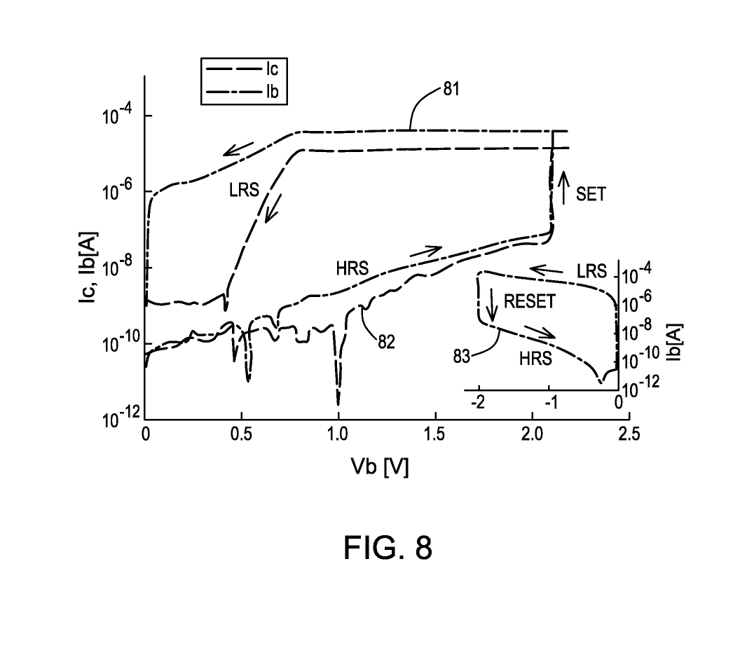

Stage 51 may be followed by stage 52 of providing to the selected programmable insulator-semiconductor bipolar transistor, via selection lines, a base emitter voltage of a value that sets a resistance of a programmable resistance layer of the selected programmable insulator-semiconductor bipolar transistor. The base emitter voltage that should be used for programming is set to cause the resistance of a programmable resistance layer to change its state, for example from a low resistive state LRS to a high resistive state HRS—such as illustrated in FIG. 8.

Method 50 may facilitate a binary programming process—programming the programmable insulator-semiconductor bipolar transistor to be in a LRS or in a HRS. But the programming can involve programming the programmable insulator-semiconductor bipolar transistor to be set to one out of more than two resistance states.

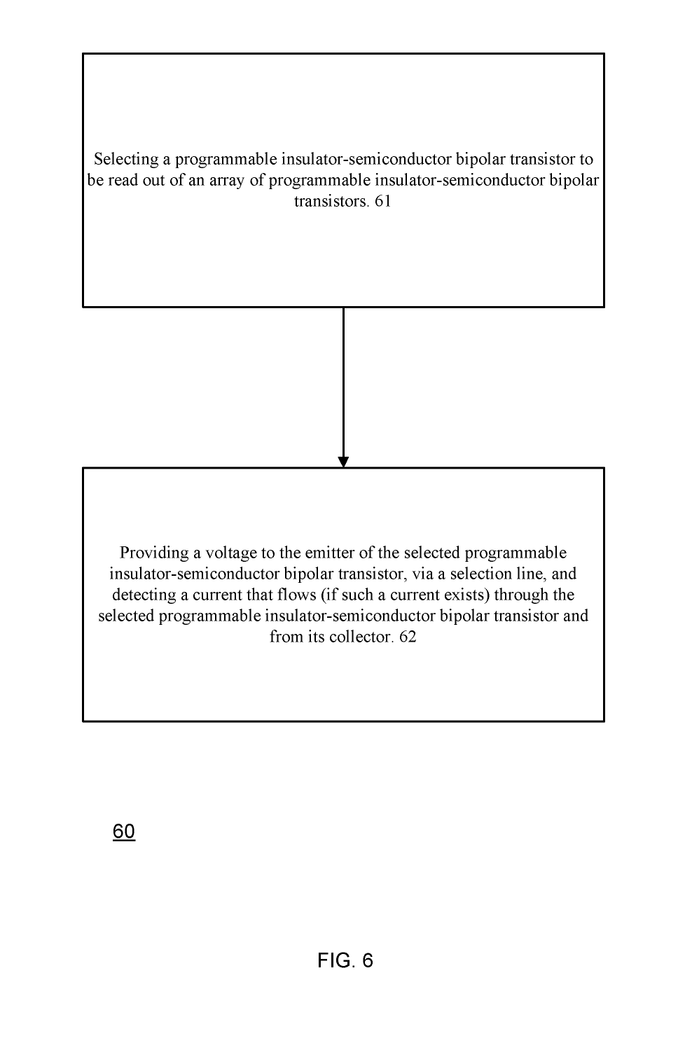

FIG. 6 illustrates method 60 for reading a programmable insulator-semiconductor bipolar transistor of an array according to an embodiment of the invention.

Method 60 may start by stage 61 of selecting a programmable insulator-semiconductor bipolar transistor to be read out of an array of programmable insulator-semiconductor bipolar transistors. In case that there is only a single transistor in the array method 60 may start by stage 62.

Stage 61 may be followed by stage 62 of providing a voltage to the emitter of the selected programmable insulator-semiconductor bipolar transistor, via a selection line, and detecting a current that flows (if such a current exists) through the selected programmable insulator-semiconductor bipolar transistor and from its collector. The absence of such a current can indicate that the selected programmable insulator-semiconductor bipolar transistor is in HRS and the sensing of current may indicate that the selected programmable insulator-semiconductor bipolar transistor is in LRS.

Method 60 may facilitate a binary read process—detecting whether the programmable insulator-semiconductor bipolar transistor to be in a LRS or in a HRS. But the reading can involve detecting one out of more than two distinguishable resistance states.

Stage 62 may include detecting an absence of a minority carrier current or a parameter of the minority carrier current (that parameter may be the presence of such a current, an amplitude of the minority carrier current and the like) that flows through the selected programmable insulator-semiconductor bipolar transistor; and determining a value stored in the selected programmable insulator-semiconductor bipolar transistor based upon an outcome of the detecting.

In bipolar programming or reading scenarios—especially when in HRS no current flows through the MIS-BT, the reading merely detects the presence or lack of current—and this may dramatically relax any gain requirements imposed on the MIS-BT.

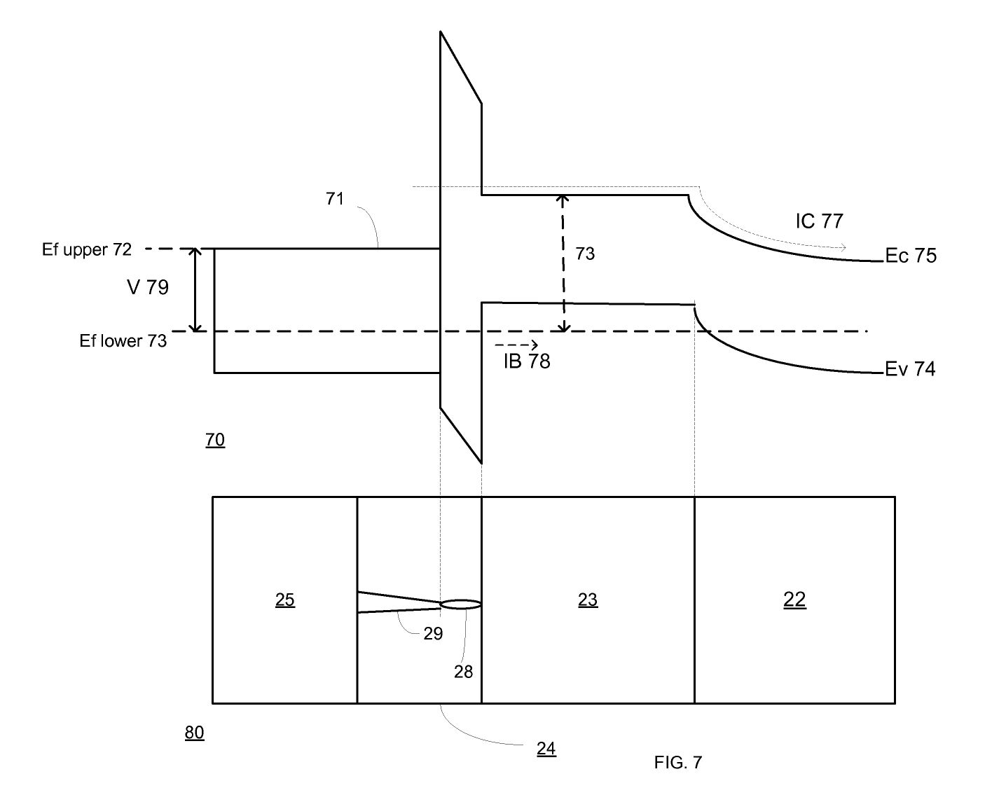

FIG. 7 includes an energy band diagram 70 of the MIS-BT at forward bias and a cross sectional view 80 of the MIS-BT 20 showing a conductive filament and a tunneling gap formed in the variable resistive layer of the MIS-BT according to an embodiment of the invention.

The emitter electrode 25 of MIS-BT is represented by a box 71 in the energy band diagram, the box 71 has an upper facet that corresponds to an upper Fermi Level (also referred to as metal Fermi level) 72.

The first semiconductor layer 23 (coupled to base electrode 25) is represented by a valance band 74 and a conduction band 75. The second semiconductor layer 22 is represented by a decrement in the valance band 74 and in the conduction band 75. A lower Fermi level (semiconductor layers Fermi level) is represented by dashed line 76.

Energy band diagram 70 also illustrates collector current (Ic) 77 that is formed by thermally excited electrons, a base current (Ib) 78 that is formed by holes, a voltage drop (V) 79 across the tunneling gap (28) that extends within the variable resistive layer 24—from an edge of a filament 29 to the first semiconductor layer, and an energy barrier for electrons when no voltage is applied Φ_{B} 73.

The thermal excitation causes electrons in the emitter electrode to leap from the metal Fermi level 72 to the conduction band of the semiconductor layer 75, which is followed by tunneling through the tunneling gap 28, and collection at a p-n junction that is formed between the first semiconductor layer 23 and the second semiconductor layer 22. This flow of electrons produces a collector current 77.

The band-gap (difference between valance and conductive bands) of InGaAs is 0.74v eV, the lower Fermi level (Ef 73) is located about 0.12 eV below the valence band edge at p=3·10¹⁹ [cm⁻³], the band-gap of HfO₂ is 5.45 eV and the band offsets (difference between corresponding GaInAs and Hf02 bands) are ΔE_{c}=1.8 eV ΔEᵥ=2.9 eV.

FIG. 8 shows the collector and base currents at positive base bias according to an embodiment of the invention. Curve 81 illustrates a first hysteresis loop that represents the base current versus base voltage at the transition from HRS to LRS. Curve 82 illustrates the collector current versus base voltage at the same hysteresis loop-transition from HRS to LRS. Curve 83 illustrates a third hysteresis loop that represents the base current at the transition from LRS to HRS (under this bias there is no collector current).

A three to four orders of magnitude “set” transition from the high resistance state (HRS) to the low resistance state (LRS) is evident. The most interesting observation is that resistive switching occurs simultaneously for electron and hole injection. This, in turn, indicates that the conduction mechanism at LRS cannot be of Ohmic nature, as further explained below. At the HRS only charging transients are measured up to about 1 V. At voltages higher than about 1 V the metal Fermi level is located above the conduction band, so both base and collector currents increase exponentially. This behavior implies that at the HRS conduction is due to tunneling (but not direct tunneling—the current density is much too high).

Curve 83 shows the base current at negative bias where the “reset” transition is observed. Only the base current is plotted because no minority carriers are injected. No additional information is obtained from this data compared to the data obtained from conventional MIM structures. Devices with different oxide thicknesses (5 nm and 20 nm) were also measured. The behavior was quite similar for all three thicknesses, except that the set voltage slightly increased with thickness, and the 20 nm devices showed less stable switching characteristics and hard breakdown of the oxide often occurred prior to forming or set.

In order to avoid damage to the base collector p-n junction we have limited the current during the “set” transition into LRS as shown in FIG. 8. Under these conditions, the measurements are reversible and repeatable. No current compliance was required at negative bias (curve 83).

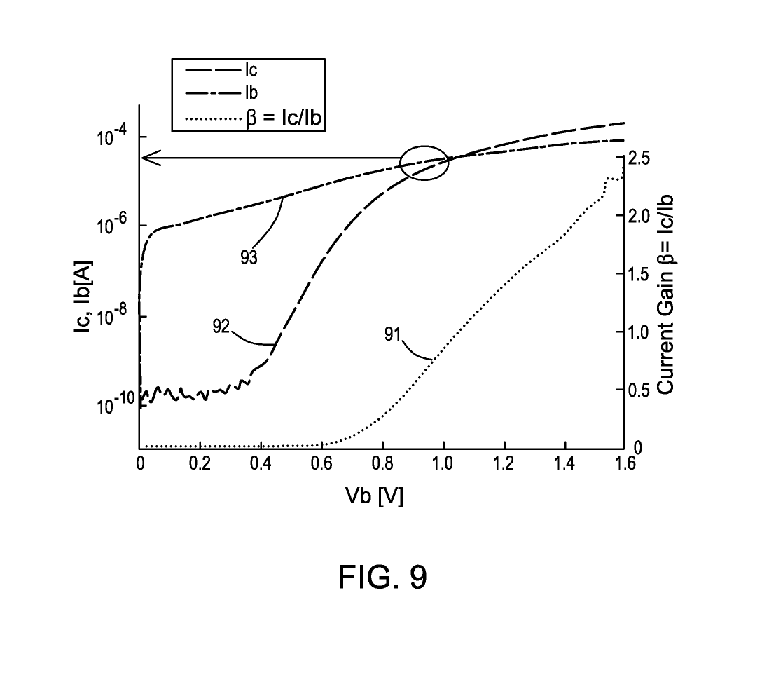

To obtain more insight on the conduction mechanism we show in FIG. 9 the base and collector currents at the LRS with no current compliance. FIG. 9 includes three curves—curve 91 illustrates a gain (ratio between collector current and base current at different base voltage Vb values), curve 92 illustrates the collector current versus base voltage and curve 93 illustrates the base current versus base voltage.

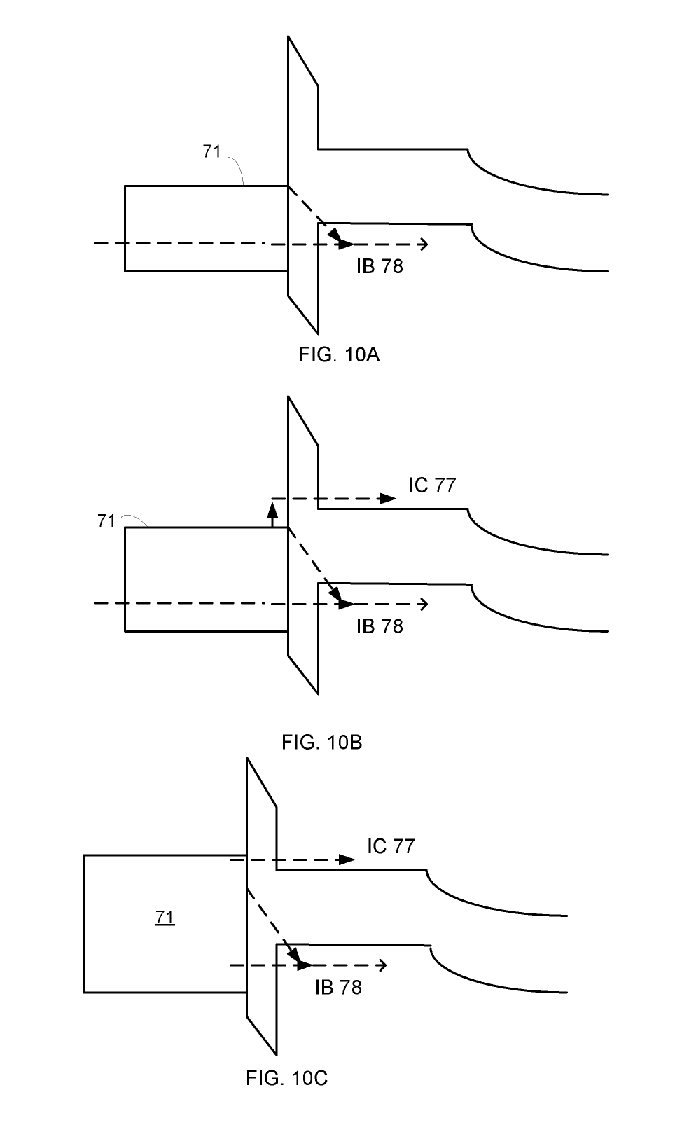

At low bias (V_{b}<0.4 V) electron injection rate into the conduction band is negligible and the base current is due to injection into the valence band as shown in FIG. 10A. At intermediate base bias levels (V_{b}˜0.5-0.8 V) electrons are thermally excited to an energy level aligned with the semiconductor conduction band, where they cross the insulator as shown schematically in FIG. 10B. The thermal excitation rate of the electrons is determined by the Boltzmann statistics. For high base bias (V_{b}>0.8V) the metal Fermi level (Ef) is located above the conduction band, and the current increases at a lower rate. At high bias the current is determined by both the conduction-band density of states and transport through the insulator (FIG. 10C).

The larger than unity current gain at bias levels larger than 1.1 V indicates that virtually all electrons are injected into the conduction band, and that recombination rate at the dielectric-semiconductor interface is low.

Before discussing the implications of the data on the validity of previously suggested conduction mechanisms we briefly comment that during forming or “set” without sufficiently low current compliance the base collector p-n junction was damaged. No change in the switching behavior of the device (the base current) was observed. We conclude from this observation that the forming and “set” processes are very energetic, as they create damage far away from the insulator. This result supports the filamentary nature of the conduction. Uniform conduction could not be sufficiently energetic to induce damage deep into the semiconductor. To illustrate this point we note that our standard bipolar GaInAs transistors can handle current densities up to 1·10⁶ A/cm². The p-n junction of the MIS-BT was damaged at ˜200 μA, which implies that the current is most probably confined to an area smaller than 10⁴ nm².

Numerous mechanisms were suggested in the literature to account for carrier transport in resistance switching oxides. Our data rules out conduction through metallic filaments connecting the top electrode and the semiconductor because such filaments should inject the current directly into the valence band (as in an Ohmic contact), and no collector current should have been detected. However, a localized conducting channel that extends most of the way across the insulating film, leaving an insulating tunneling gap, is consistent with our results. In this case, the applied voltage drops across the tunneling gap, and electrons are injected directly by tunneling into the conduction band, as in a tunneling emitter bipolar transistor.

The obtained data also rules out Mott hopping through trap states: no collector current is expected in this case if the trap level is located below the conduction band, and constant current gain is expected if the trap level is located above the conduction band. Moreover, the thermal injection rate into traps that are located above the conduction band is too low to account for the large measured current densities. Another model that may explain our data is tunneling between adjacent sites within a broad impurity band aligned. However, a broad localized impurity band in HfO₂ was not found in ab-initio calculations and is hard to justify theoretically. We finally note that the similarity of the data reported here to that obtained for resistive switching in Al₂O₃ suggests that a general conduction mechanism exists in thin metal oxides, possibly taking into account one-dimensional transport.

A metal insulator bipolar transistor structure was applied to study resistive switching in HfO₂. Injection of electrons into the conduction band of the semiconductor through HfO₂ was observed for the first time. The LRS conduction model that best explains the results is the formation of conductive filaments that extend through most of the films, leaving a small tunneling gap.

Filament Temperature Measurements

The resistive switching effect in metal oxides and other dielectric materials is among the leading future non-volatile memory technologies. Resistive switching is widely ascribed to the formation and rupture of conductive filaments in the oxide, which are generated by temperature enhanced nano-scale ion migration or other thermal effects. In spite of the central role of the local filament temperature on the switching effect, as well as on the conduction and reliability physics, no measurements of the filament temperature are yet available. There is provided a new method for measuring the conducting filament temperature, using a metal-insulator-semiconductor bipolar transistor structure. The filament temperature is obtained by analyzing the thermal excitation rate of electrons from the filament Fermi level into the conduction band of a p-type semiconductor electrode. Measurements were carried out to obtain the conductive filament temperature at varying ambient temperatures in the range of 3 K to 300 K. Significant Joule heating of the filament was measured across the entire temperature range, yielding important physical insight into the resistive switching effect.

The resistance switching effect is widely attributed to the formation and rupture of conductive nano-filaments in the insulating matrix due to nano-ionic and thermal effects. The mechanisms most relevant to metal oxides are valence change, thermo-chemical, and electrochemical metallization effects. In all three cases the conductive filaments are believed to be composed of reduced metal-oxides (or metal in the extreme case) formed in the stoichiometric oxide.

Within the valence change model, oxygen vacancies migrate due to the applied electric field, resulting in change of stoichiometry and a reduction-oxidation (redox) reaction. Elevated filament temperatures enhance the ionic mobility of oxygen vacancies. The redox is expressed by valence change of the metal cation followed by a change in electronic conductivity. In the thermo-chemical case, a change of stoichiometry occurs due to current induced heating. Within the electrochemical metallization effect metal cations drift away from an electrochemical reactive electrode towards the counter (inert) electrode, where they discharge and form a metal filament. The metal filament dissolves when opposite bias is applied. All above mentioned effects may require elevated temperatures, which are expected because the current that flows through the filaments is confined to a nanometric cross-section, and the current density in the filament is extremely high. Joule heating of the filament must therefore be substantial. To the best of our knowledge, measurements of the filament temperature were not yet reported, and only model calculations are available.

The experimental monitoring of filament temperature may be vital for the resistive switching technology due to several reasons. As outlined above, the filament temperature is a critical parameter that determines the switching process in all relevant switching mechanisms. In addition, filament temperature must be known when the temperature dependence of the conductivity or of other effects is studied, because the ambient temperature is in most cases much lower than the filament temperature. Finally, monitoring the filament temperature is imperative for enhancing the reliability of any switching device.

The suggested temperature measurement is based upon the MIS-BT, which provides information on the energy of electrons injected through insulating materials.

Electrons injected from the metal emitter into the base conduction band must obtain the required energy from thermal excitation. By measuring the electron minority carrier current the temperature of the filament tip can thus be evaluated.

At the low resistance state, electrons flow from the metal electrode through the conductive filament into the p-type semiconductor. Those electrons which are injected into the semiconductor conduction band are minority carriers. They are collected by the electric field in the depletion region of the base collector junction, and are detected as collector current.

The collector current provides information on the temperature of the conductive filaments because electrons are thermally excited from the filament tip in order to reach the conduction band. Electrons injected into the valence band are majority carriers, which are detected as base current. Minority carriers that recombine in the base or at the interface, as well as electrons injected into interface mid-gap states, are also detected as base current.

The model that was suggested to explain the current voltage characteristics of the device is as follows. When the insulator between the metal electrode and the semiconductor is in its low resistance state, a filament extends through most of the film, leaving a small tunneling gap adjacent to the semiconductor electrode. Conduction takes place by direct tunneling through the ultrathin gap. The existence of a tunneling gap was also suggested by Pickett et al. to account for their experimental results in two terminal devices. Due to the high current density in the filament, the transmission coefficient through the gap must be fairly high, and its width must thus be of the order of 1 nm or even less. Our results indicated that most of the applied voltage drops across the tunneling gap, and consequently most of the heat is dissipated in the electrodes rather than in the filament.

There is further provided an explanation of a method for measurement of filament temperature. Electron injection from the filament Fermi level into the p-type base conduction band (measured as the collector current) is impeded by an energy barrier (Φ_{B}−V), where V is the voltage drop across the tunneling gap, and Φ_{B}=(E_{g}+−ₚ) is the energy barrier at V=0.

Assuming no reflections, the electron current density from the filament into the semiconductor is given by:

$$J = \frac{4 π m * k}{{h}^{3}} \cdot T {\int }_{{E}_{C}}^{∞} ln [ 1 + exp ( - \frac{( E - {E}_{F} )}{kT} ) ] d E \qquad ( 1 )$$

where T is the varying temperature which we wish to measure, E the electron energy, m* the effective mass, k Botlzmann's constant, h Planck's constant, E_{F} the Fermi level position, and E_{C} the semiconductor conduction band minima.

To proceed, we introduce the tunneling transmission probability through the barrier, P, which we assume does not depend on the applied bias, since the barrier is very thin and electrons cross it by direct tunneling. We also neglect the reflection (or more importantly its temperature dependence) due density of states related effects in the semiconductor. The semiconductor Fermi level is denoted as E=0, the position of the conduction band minima is at E_{C}=Φ_{B}, the metal Fermi level is determined by the applied voltage, namely E_{F}=qV, and S is the filament tip area.

One thus obtains that the collector current is given by

$${I}_{C} = S \cdot P \cdot \frac{4 π m * k}{{h}^{3}} \cdot T {\int }_{{φ}_{B}}^{∞} ln [ 1 + exp ( - \frac{( E - qV )}{kT} ) ] d E \qquad ( 2 )$$

At relatively low bias, the energy barrier is much larger than the thermal energy Boltzmann statistics apply and the Richardson equations is obtained:

$${I}_{C} = S \cdot P \cdot A * {T}^{2} exp [ \frac{- ( {Φ}_{B} - qV )}{kT} ] \qquad ( 3 )$$

where A* is the effective Richardson constant.

We have assumed in the above derivation that the resistance of the filament is small, and that the applied voltage at the base terminal, V_{B}, equals the voltage across the tunneling gap. Otherwise, at high current density the quasi Fermi level at the filament tip would be located at the same energy as the semiconductor quasi Fermi level, and no injection into the conduction band would be detected.

From equation (3) one obtains that allow applied bias

$$\frac{d ln ( {I}_{C} )}{d {V}_{B}} = \frac{d T}{d {V}_{B}} [ \frac{{Φ}_{B} - {qV}_{B}}{{kT}^{2}} - \frac{2}{T} ] + \frac{q}{kT} .$$

The temperature at the tip of the filament is extracted by numerically solving equation (4) across the range Boltzmann statistics applies. The full procedure for extracting the temperature across the entire range is described in the supplemental material section. The product of the filament cross section and tunneling probability can be obtained by fitting equation (3) to the experimental data using the extracted temperatures.

Experimental Evaluation of Filament Tip Temperature

The extraction method was applied to measure the temperature of conducting filaments generated in a thin layer of HfO₂. The p⁺⁺n junction material was Ga_{0.47}In_{0.53}As epitaxially grown on InP. The current-voltage characteristics of the devices were measured at room temperature and at 3 K. The current was limited during the switching process to prevent damage to the device.

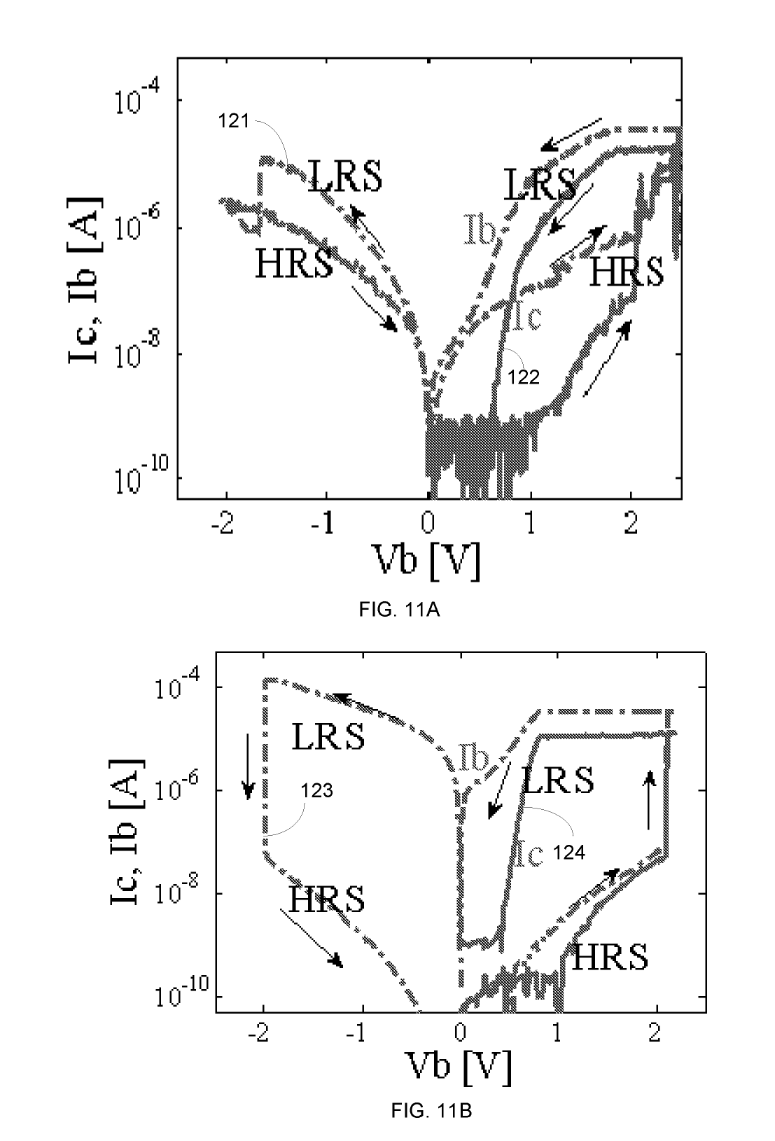

FIGS. 11A and 11B include curves 121-124 that show the room temperature collector and base currents versus base voltage of two devices having a 6 and 10 nm thick HfO₂ layers. The observed bipolar switching characteristics suggest that the valence change effect is the dominant switching mechanism. The experimental results shown in FIGS. 11A-11B are briefly summarized below.

At low base bias (Vb<0.4 V) electron injection rate into the conduction band is lower than the noise current. Base current is due to injection into the valence band.

At intermediate base bias levels (Vb˜0.5-0.85 V) electrons are injected by thermal assisted tunneling into the conduction band.

For high base bias (Vb>0.85V) the metal Fermi level is located above the conduction band, electrons are injected by direct tunneling, and as a result the collector current increases at a lower rate. Note that at high applied voltage the collector current is of the same order of the base current indicating that a large fraction of the electrons is injected into the conduction band.

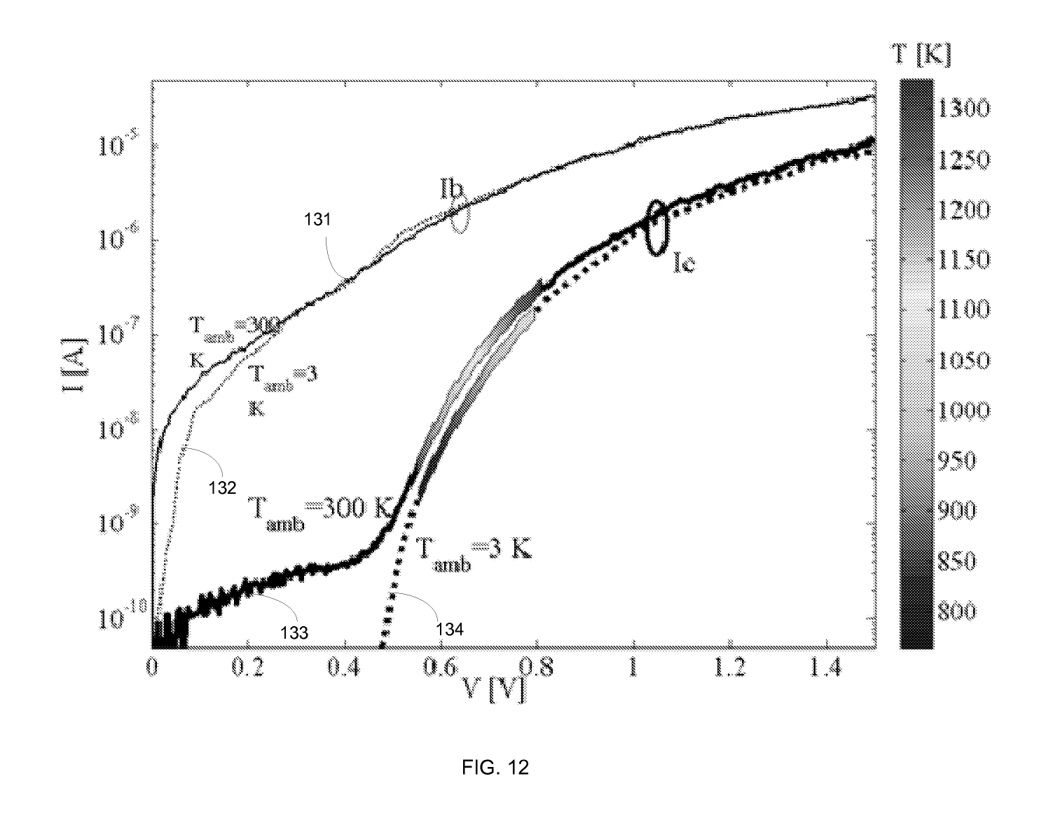

FIG. 12 includes curves 131-134 illustrate collector (electron) currents versus base-emitter voltage at the low resistance state of a typical metal-insulator-semiconductor bipolar transistor at 3 K and 300 K. The color-map shows the extracted temperature. Inset shows both base (holes) and collector (electrons) currents.

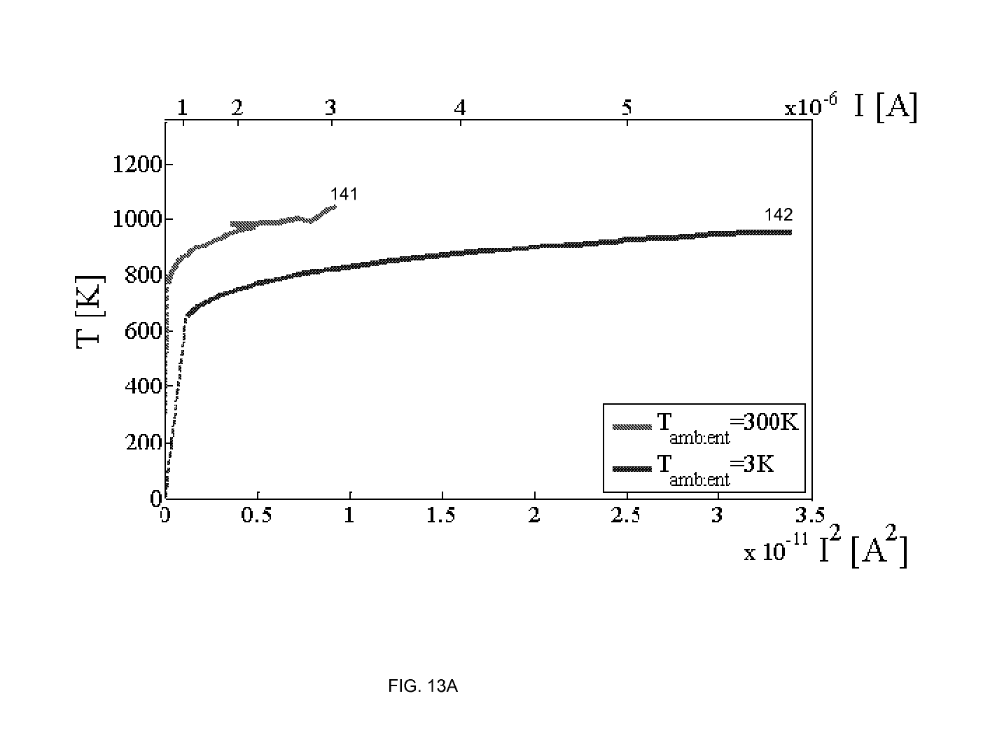

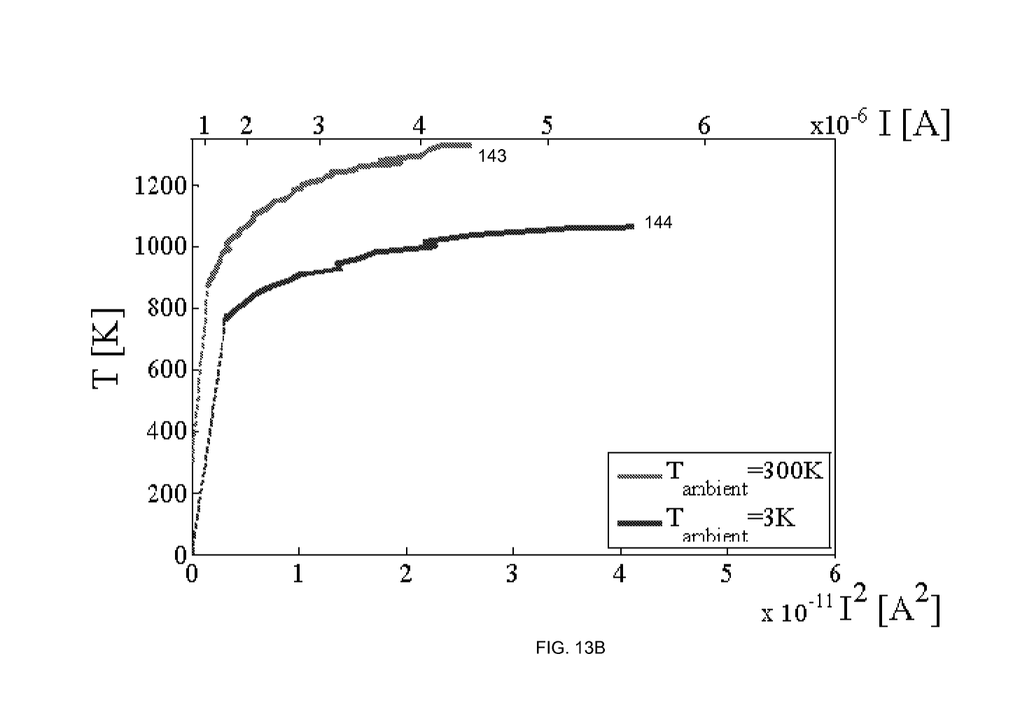

FIGS. 13A-13B include curves 141-144 that show the base and collector currents of one of the devices at the low resistance state, and the extracted filament temperatures. Ambient temperatures of the device were 3 K and room temperature.

By merely inspecting the raw data, the similarity between the collector current curves at 3 K and at room temperatures indicates that the filaments are not at ambient temperature. At 3 K, no injection of electrons from the filament Fermi level into the conduction band can take place, and no collector current is expected, unless the filaments are at a higher temperature than 3 K. The extracted temperatures shown in the figure, confirm this conclusion. The base current is almost identical at the two shown temperatures. It is due to direct tunneling into the valence band and interface states, and (unlike the collector current) is hence almost independent of filament temperature. When the device is biased to relatively high voltage, so that the metal Fermi level is located above the semiconductor conduction band minima, the collector current is insensitive to filament temperature because no thermal excitation is required any more. In this range, the temperature can therefore not be extracted.

FIGS. 13A and 13B illustrate extracted filament temperatures in two different metal-insulator-semiconductor bipolar transistors at ambient temperatures of 3 K and 300 K as a function of the total (base+collector) current squared. The top x-axis shows the actual current. The dashed straight line is a guide to the eye to roughly evaluate the filament temperature at low currents, where it was not measured.

The filament temperature extraction procedure was conducted on several MIS-BTs at ambient temperatures of 3 K and 300 K.

FIGS. 13A and 13B include curves 141-144 that show the obtained results from two representative devices. The temperature is plotted versus the squared sum of base and collector currents, which is proportional to the power dissipated in the filament. We note that substantial heating of the filament is observed in all devices, and that the heating effect is quite different in the two devices, reflecting the random nature of filament formation. The obtained filament temperature range is in reasonable agreement with model calculations considering the dimensions of the filament. At low current, the filament temperature could not be evaluated, because the collector current was below the noise limit. We have therefore added a straight line as a guide to the eye to help evaluate filament temperature at low current.

We estimate the temperatures during the switching events by comparing FIGS. 13A and 13B to the switching characteristics shown in FIGS. 11A-11B.

The set process, namely switching from HRS to LRS, occurs at relatively low total current ˜0.1 micro Ampere. It is not known if at HRS the current flows through filaments or not, but maximal heating would take place if it does. Therefore, our results indicate that switching from HRS to LRS takes place at filament temperatures lower than 600 K. The reset process (switching from LRS to HRS), on the other hand, occurs at high currents ˜10-100 micro Ampere, and our results imply that this process requires higher temperatures of the order of 1200 K. Our data furthermore indicates that if the readout current is lower than about 0.1 micro Ampere, no significant heating takes place.

Our results can now be compared to the prediction of various switching models in the Ti/HfO₂ system. The field accelerated ionic mobility model of oxygen vacancies may explain the “set” event which takes place at lower temperature. The “reset” event, however, may be triggered by the “temperature accelerated” ionic mobility. Another possible explanation for the “reset” event is the thermal dissolution of the conductive filament as in unipolar case. Yet another possible interpretation to the set/reset temperature asymmetry is that the electric field and the vacancies gradient point at the same direction in the “set” process and at opposite directions in the “reset” process.

We have assumed throughout this work that because a single switching event is observed, the current flows through a single filament. The product of filament area by the tunneling probability can be found, as explained in the supplementary material section. The obtained values are in the range of 1-100 nm², in agreement with previous estimates of filament diameters, assuming a reasonable tunneling probability through the thin gap of 10⁻²−1.

Restive Switching at 3 K

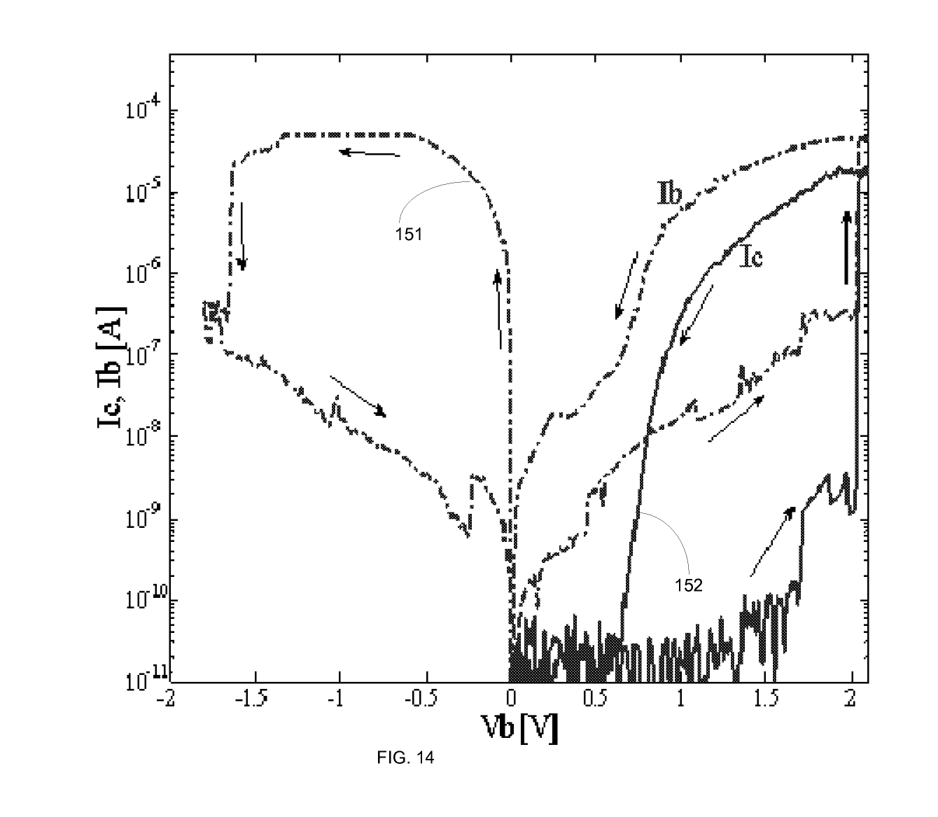

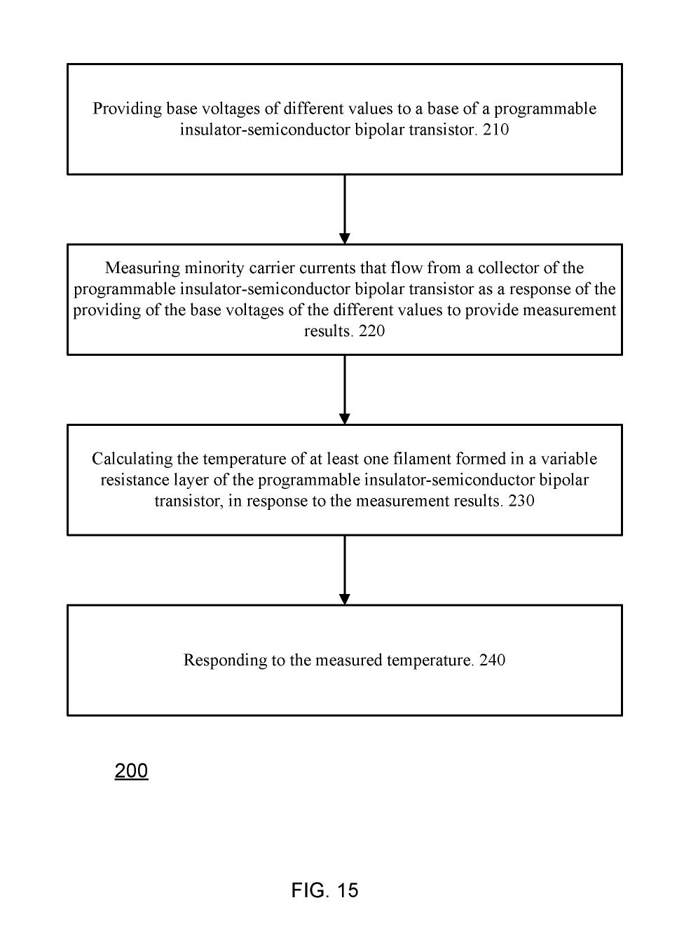

FIG. 14 includes curves 151 and 152 that illustrate base (hole) and collector (electron) currents versus base-emitter voltage showing switching behavior of a device at ambient temperature of 3 K.

The data presented in FIG. 14 is to the best of our knowledge the first report on resistive switching in metal oxides near zero temperature. As evident in the figure, the switching behavior at 3 K is quite similar to that observed at room temperature. Combined with the temperature measurements, it indicates that the “set” event takes place at temperatures lower than room temperature, and the “reset” event at high temperatures. The implications for switching modeling were discussed above.

It was theoretically predicted by many authors that the conducting filament temperature in resistive switching materials is much higher than the ambient temperature. We have described in this work an experimental method for obtaining the filament temperature, and measured the conductive filament temperature in HfO₂ at 3 K and 300 K. The obtained temperatures at current levels larger than about 1 micro Ampere were indeed much higher than the device ambient temperature.

Our measurements may be crucial for correctly interpreting studies of the temperature dependence of the electric conduction in restive switching materials. In this type of experiments, one must bear in mind that in many cases the filament temperature is much higher than the ambient temperature. In addition, experimental evaluation of the filament temperature may help improve resistive switching device reliability, and better explain the switching mechanism.

The epitaxial semiconductor stack was grown by a compact metal organic molecular beam epitaxy system. CBr₄ served as source for p-type dopant atoms. The insulating HfO₂ layers were deposited by atomic layer deposition. The layer structure of the device was shown in Table I. The HfO₂ layers were wet etched using HF:H₂O (1:5) solution. The metal stack was prepared by the lift-off technique. Devices with emitter area of 22×45 m², and 100×100 m² were fabricated by standard photolithography. Semiconductor parameter analyzer was used for the three terminal current-voltage measurements. The cooling system for low temperature measurements is based on a Cryomech Pulse Tube Cryorefrigerator built into a modified cryostat. The ambient temperature was monitored using a Lakeshore temperature controller model 335 and a Lakeshore temperature sensor model DT-470 (Silicon Diode) with typical accuracy of 1 K.

FIG. 16 illustrates method 200 for measuring a filament temperature according to an embodiment of the invention.

Method 200 may start by stage 210 of providing base voltages of different values to a base of a programmable insulator-semiconductor bipolar transistor.

Stage 210 may be followed by stage 220 of measuring minority carrier currents that flow from a collector of the programmable insulator-semiconductor bipolar transistor as a response of the providing of the base voltages of the different values to provide measurement results.

Stage 220 may be followed by stage 230 of calculating the temperature of at least one filament formed in a variable resistance layer of the programmable insulator-semiconductor bipolar transistor, in response to the measurement results. Wherein the at least one filament is formed when the programmable insulator-semiconductor bipolar transistor is programmed to a certain value out of multiple programmable values, wherein the at least one filament facilitates a flow of minority carriers from an emitter of the programmable insulator-semiconductor bipolar transistor towards the collector.

Stage 230 may include any of the following:
a. Calculating of the temperature in response to a derivative of the minority carrier current with respect to the base voltage.
b. Calculating of the temperature in response to a charge (q) of a minority carrier, Boltzman's constant (K), and a value of an energy barrier (ΦB) that is formed for a certain voltage drop across a tunneling gap formed between each of the at least one filament and a semiconductor layer of the programmable insulator-semiconductor bipolar transistor.
c. Solving the following equation:

$$\frac{d ln ( {I}_{C} )}{d {V}_{B}} = \frac{d T}{d {V}_{B}} [ \frac{{Φ}_{B} - {qV}_{B}}{{kT}^{2}} - \frac{2}{T} ] + \frac{q}{kT} ,$$

wherein d ln(Ic)/dVb is a derivative of a logarithm of a collector current with respect with a base voltage; wherein _{Φ}B represents an energy barrier formed between metal Fermi level and conduction band of a semiconductor layer formed in the programmable insulator-semiconductor bipolar transistor, wherein dT/dVb is a derivative of a filament temperature with respect to the base voltage.
d. Calculating the filament temperature in response to filament tip area (S), to a tunneling transmission probability (P) through the filament and into a semiconductor layer of the insulator-semiconductor bipolar transistor; to a minority carrier effective mass (m*), to a charge (q) of a minority carrier, to an energy barrier (ΦB), and to Boltzman's constant (k).
e. Solving the following equation:

$${I}_{C} = S \cdot P \cdot \frac{4 π m * k}{{h}^{3}} \cdot T {\int }_{{φ}_{B}}^{∞} ln [ 1 + exp ( - \frac{( E - qV )}{kT} ) ] d E .$$

f. Calculating the filament temperature in response to filament tip area (S), to a tunneling transmission probability (P) through the filament and into a semiconductor layer of the insulator-semiconductor bipolar transistor; to An effective Richardson constant (A*), to a charge (q) of a minority carrier, to an energy barrier (_{Φ}B), and to Boltzman's constant (k).
g. Solving the following equation:

$${I}_{C} = S \cdot P \cdot A * {T}^{2} exp [ \frac{- ( {Φ}_{B} - qV )}{kT} ]$$

Stage 230 may be followed by stage 240 of responding to the measured temperature. Stage 230 may include shutting down a MIT-BS element that may be overheated, cooling down the MIT-BS and the like.

Supplemental Material

Numerical Procedure for Extraction of Filament Temperature

In the first step of the procedure, the temperature at low applied voltage is obtained. Its value is needed as a boundary condition for numerically solving equation (2). We define β=q/ηkT, and neglect (at a single point at low bias only) the temperature dependence of the pre-exponents in equation (3) to rewrite equation (4) as follows:

$${( \frac{d ln ( {I}_{C} )}{d V} )}_{i} = {β}_{i} - \frac{d {β}_{i}}{d {V}_{i}} ( \frac{{Φ}_{B}}{q} - {V}_{i} ) \qquad ( 5 )$$

where i denotes the index of the measured voltage and current vectors. The equivalent matrix notation is:

$$( \begin{matrix}\frac{d ln ( {I}_{C} )}{d {V}_{i - 1}} \\ \frac{d ln ( {I}_{C} )}{d {V}_{i}} \\ \frac{d ln ( {I}_{C} )}{d {V}_{i + 1}}\end{matrix} ) = ( \begin{matrix}\frac{{ln ( {I}_{C} )}_{i} - {ln ( {I}_{C} )}_{i - 2}}{{V}_{i} - {V}_{i - 2}} \\ \frac{{ln ( {I}_{C} )}_{i + 1} - {ln ( {I}_{C} )}_{i - 1}}{{V}_{i + 1} - {V}_{i - 1}} \\ \frac{{ln ( {I}_{C} )}_{i + 2} - {ln ( {I}_{C} )}_{i}}{{V}_{i + 2} - {V}_{i}}\end{matrix} ) \qquad ( 6 )$$

equation (5) thus becomes:

$$( \begin{matrix}\frac{{ln ( {I}_{C} )}_{i} - {ln ( {I}_{C} )}_{i - 2}}{{V}_{i} - {V}_{i - 2}} \\ \frac{{ln ( {I}_{C} )}_{i + 1} - {ln ( {I}_{C} )}_{i - 1}}{{V}_{i + 1} - {V}_{i - 1}} \\ \frac{{ln ( {I}_{C} )}_{i + 2} - {ln ( {I}_{C} )}_{i}}{{V}_{i + 2} - {V}_{i}}\end{matrix} ) = ( \begin{matrix}1 & \frac{( \frac{{Φ}_{B}}{q} - {V}_{i - 1} )}{2 ( {V}_{i} - {V}_{i - 2} )} & 0 \\ - \frac{( \frac{{Φ}_{B}}{q} - {V}_{i} )}{2 ( {V}_{i + 1} - {V}_{i - 1} )} & 1 & \frac{( \frac{{Φ}_{B}}{q} - {V}_{i} )}{2 ( {V}_{i + 1} - {V}_{i - 1} )} \\ 0 & - \frac{( \frac{{Φ}_{B}}{q} - {V}_{i + 1} )}{2 ( {V}_{i + 2} - {V}_{i} )} & 1\end{matrix} ) \cdot ( \begin{matrix}{β}_{i - 1} \\ {β}_{i} \\ {β}_{i + 1}\end{matrix} ) \qquad ( 7 )$$

from which one can obtain the vector by matrix inversion:

$$( \begin{matrix}{β}_{i - 1} \\ {β}_{i} \\ {β}_{i + 1}\end{matrix} ) = {( \begin{matrix}1 & \frac{( \frac{{Φ}_{B}}{q} - {V}_{i - 1} )}{2 Δ {V}_{i - 1}} & 0 \\ - \frac{( \frac{{Φ}_{B}}{q} - {V}_{i} )}{2 Δ {V}_{i}} & 1 & \frac{( \frac{{Φ}_{B}}{q} - {V}_{i} )}{2 Δ {V}_{i}} \\ 0 & - \frac{( \frac{{Φ}_{B}}{q} - {V}_{i + 1} )}{2 Δ {V}_{i + 1}} & 1\end{matrix} )}^{- 1} \cdot ( \begin{matrix}\frac{Δ ln ( {I}_{C} )}{Δ {V}_{i - 1}} \\ \frac{Δ ln ( {I}_{C} )}{Δ {V}_{i}} \\ \frac{Δ ln ( {I}_{C} )}{Δ {V}_{i + 1}}\end{matrix} ) \qquad ( 8 )$$

A numerical solution to equation (4) can be found with the boundary condition given from (8). Having found the varying temperature at the bias levels where Boltzmann statistics apply, the S·P product is given by equation (3). Since we have assumed that S·P does not vary with applied bias, the filament temperature can be extracted for the entire voltage range by numerically solving equation (3).

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will be appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also for example, the examples, or portions thereof, may implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems’.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A programmable insulator-semiconductor bipolar transistor, comprising:
a substrate,
a first semiconductor layer;
a second semiconductor layer;
a variable resistance layer;
an emitter electrode;
a collector electrode; and
a base electrode;
wherein the collector electrode is coupled to the substrate;
wherein the variable resistance layer is coupled between the emitter electrode and the first semiconductor layer;
wherein the second semiconductor layer is coupled between the substrate and the first semiconductor layer;
wherein the first and second semiconductor layer define a p-n junction;
wherein the variable resistance layer facilitates a flow of minority carriers from the emitter electrode towards the first and second semiconductor layers when being programmed to be of a high resistance value and wherein the variable resistance layer substantially is arranged to act as an insulator when being programmed to be of a low resistance value; wherein the high resistive value exceeds the low resistive layer.

2. The programmable insulator-semiconductor bipolar transistor according to claim 1 wherein the variable resistance layer is made of Hf02.

3. The programmable insulator-semiconductor bipolar transistor according to claim 1, wherein the first semiconductor layer is a p-type doped semiconductor layer and the second semiconductor layer is an n-type doped semiconductor layer.

4. The programmable insulator-semiconductor layer bipolar transistors according to claim 1, wherein the emitter electrode spans along an entire upper surface of the variable resistance layer.

5. A memory device, comprising:
selection circuitry;
an array of programmable insulator-semiconductor bipolar transistors, each programmable insulator-semiconductor bipolar transistor comprises a substrate, a first semiconductor layer; a second semiconductor layer; a variable resistance layer; an emitter electrode; a collector electrode; and a base electrode; wherein the collector electrode is coupled to the substrate; wherein the variable resistance layer is coupled between the emitter electrode and the first semiconductor layer; wherein the second semiconductor layer is coupled between the substrate and the first semiconductor layer; wherein the first and second semiconductor layer define a p-n junction; wherein the variable resistance layer facilitates a flow of minority carriers from the emitter electrode towards the first and second semiconductor layers when being programmed to be of a high resistance value and wherein the variable resistance layer substantially is arranged to act as an insulator when being programmed to be of a low resistance value; wherein the high resistive value exceeds the low resistive layer; and
a read circuit;
a write circuit;
wherein the selection circuitry comprises a controller, multiple column selection lines, and multiple row selection lines;
wherein each column selection line is coupled to base electrodes of programmable insulator-semiconductor bipolar transistors that belong to a column of the array;
wherein each row selection line is coupled to emitter electrodes of programmable insulator-semiconductor bipolar transistors that belong to a row of the array;
wherein the read circuit is coupled to collector electrodes of multiple programmable insulator-semiconductor bipolar transistors of the array;
wherein the write circuit is arranged to provide a programming voltage between a base electrode and an emitter electrode of a programmable insulator-semiconductor bipolar transistor selected by the selection circuitry; wherein a value of the programming voltage determines a value of the variable resistance layer of the selected programmable insulator-semiconductor bipolar transistor.

6. The memory device according to claim 5, wherein the write circuit is arranged to set the value of the variable resistance layer to a high resistance value that substantially prevents minority carriers to flow through the variable resistance layer.

7. The memory device according to claim 5, wherein the write circuit is arranged to set the value of the variable resistance layer to a high resistance value that allows minority carriers to flow through the variable resistance layer.

8. The memory device according to claim 5, wherein the write circuit is arranged to set the value of the variable resistance layer to a value out of more than two distinguishable values.

9. The memory device according to claim 8 wherein the read circuit is arranged to distinguish between the at least two distinguishable values.

10. (canceled)

11. (canceled)

12. A method for measuring a temperature (T) of a filament, the method comprises:
providing base voltages of different values to a base of a programmable insulator-semiconductor bipolar transistor;
obtaining measurement results by measuring a minority carrier current that flows from a collector of the programmable insulator-semiconductor bipolar transistor in response to the providing of the base voltages of the different values; and
calculating the temperature of the filament, based upon the measurement results;
wherein the filament is formed in a variable resistance layer of the programmable insulator-semiconductor bipolar transistor when the programmable insulator-semiconductor bipolar transistor is programmed to a certain value out of multiple programmable values, wherein the filament facilitates a flow of minority carriers from an emitter of the programmable insulator-semiconductor bipolar transistor towards the collector.

13. The method according to claim 12, wherein the calculating of the temperature is responsive to a derivative of the minority carrier current with respect to the base voltage.

14. The method according to claim 13, wherein the calculating of the temperature is further responsive to a charge (q) of a minority carrier, Boltzman's constant (K), and a value of an energy barrier Φ_{B}, that is formed for a certain voltage drop across a tunneling gap formed between the filament and a semiconductor layer of the programmable insulator-semiconductor bipolar transistor.

15. The method according to claim 14, wherein the calculating of the temperature comprises solving the following equation:
$$\frac{d ln ( {I}_{C} )}{d {V}_{B}} = \frac{d T}{d {V}_{B}} [ \frac{{Φ}_{B} - {qV}_{B}}{{kT}^{2}} - \frac{2}{T} ] + \frac{q}{kT} ,$$
wherein d ln(Ic)/dVb is a derivative of a logarithm of a collector current with respect with a base voltage; wherein ΦB represents an energy barrier formed between valance and conduction bands of a p-n junction formed in the programmable insulator-semiconductor bipolar transistor, wherein dT/dVb is a derivative of a temperature with respect to the base voltage.

16. The method according to claim 12, wherein the calculating of the temperature is responsive to a filament tip area (S), to a tunneling transmission probability (P) through the filament and into a semiconductor layer of the insulator-semiconductor bipolar transistor; to a minority carrier mass (m*), to a charge (q) of a minority carrier, to an energy barrier (ΦB), and to Boltzman's constant (k).

17. The method according to claim 16, wherein the calculating of the temperature comprises solving the following equation:
$${I}_{C} = S \cdot P \cdot \frac{4 π m * k}{{h}^{3}} \cdot T {\int }_{{φ}_{B}}^{∞} ln [ 1 + exp ( - \frac{( E - qV )}{kT} ) ] d E .$$

18. The method according to claim 12, wherein the calculating of the temperature is responsive to filament tip area (S), to a tunneling transmission probability (P) through the filament and into a semiconductor layer of the insulator-semiconductor bipolar transistor; to An effective Richardson constant (A*), to a charge (q) of a minority carrier, to an energy barrier (ΦB), and to Boltzman's constant (k).

19. The method according to claim 18, wherein the calculating of the temperature comprises solving the following equation:
$${I}_{C} = S \cdot P \cdot A * {T}^{2} exp [ \frac{- ( {Φ}_{B} - qV )}{kT} ] .$$

20. The method according to claim 12, further comprising responding to the calculating of the temperature.

21. The method according to claim 20 wherein the responding comprises reducing a temperature of the programmable insulator-semiconductor bipolar transistor.
